(19) United States
(12) Patent Application Publication
(10) Pub. No.: US 2026/0206584 A1
(43) Pub. Date: Jul. 16, 2026

(54) IRREGULAR DIRECT BONDED METAL (DBM) AND CONNECTION SUBSTRATE

(71) Applicant: SEMICONDUCTOR COMPONENTS INDUSTRIES, LLC, Scottsdale, AZ (US)

(72) Inventors: XiaoYing YUAN, Suzhou (CN); DingHao WU, Suzhou (CN); AnAn XING, Suzhou (CN); Cheng HU, Suzhou (CN); Jie CHANG, Suzhou (CN); Keunhyuk LEE, Suzhou (CN)

(73) Assignee: SEMICONDUCTOR COMPONENTS INDUSTRIES, LLC, Scottsdale, AZ (US)

(21) Appl. No.: 19/022,259

(22) Filed: Jan. 15, 2025

(51) Int. Cl. H01L 23/373; H01L 21/48; H01L 23/00; H01L 23/367; H01L 23/495; H01L 25/16; H10D 80/20; H10D 80/30

(52) U.S. Cl. CPC H10W 40/255; H10W 70/041; H10W 70/417; H10W 90/811; H10D 80/20; H10D 80/30; H10W 40/226; H10W 42/121; H10W 72/07331; H10W 72/07553; H10W 72/531; H10W 72/536; H10W 72/5363; H10W 72/537; H10W 72/5445; H10W 72/884; H10W 90/00; H10W 90/736; H10W 90/756

(57) ABSTRACT

Described implementations provide an apparatus that includes a conductive portion of a package, including a die attach pad (DAP), a semiconductor die coupled to the DAP, and a direct bonded metal (DBM) substrate including at least a metal layer coupled to a dielectric layer, the semiconductor die and the DAP being included in a first vertical stack separated from a second vertical stack including the DBM substrate.

### TECHNICAL FIELD

This description relates to semiconductor packaging techniques for power modules.

### BACKGROUND

Semiconductor devices have been developed for use in various applications associated with power supply and power management. For example, power modules may use a combination of a transistor and a diode, such as an Insulated Gate Bipolar Transistor (IGBT) and a Fast Recovery Diode (FRD). Power modules may also include integrated circuits (ICs). Semiconductor devices packaged within a power module may have high demands in terms of electrical, mechanical, and thermal reliability.

Integrated circuit packaging is the final stage of semiconductor device fabrication, in which the semiconductor die, or dies are encapsulated in a package that prevents physical damage and corrosion. The package supports the electrical contacts which connect the semiconductor devices to a circuit board. An integrated circuit package or semiconductor device package includes a metal, plastic, glass, or ceramic casing containing one or more semiconductor devices or integrated circuits. Individual components are fabricated on semiconductor wafers (commonly silicon, or silicon carbide wafers) before being diced into die, tested, and packaged. The semiconductor device package provides a means for connecting the semiconductor devices or integrated circuits to the external environment, such as a printed circuit board, via leads such as lands, balls, or pins and provides a means for protection against threats such as mechanical impact, chemical contamination, and/or light exposure. An example package may include multiple semiconductor die mounted on a substrate. With an increasing demand for high-performance integrated circuits, new improvements are needed in packaging technologies to improve the performance and reliability of integrated circuits.

### SUMMARY

In some aspects, the techniques described herein relate to an apparatus, including: a conductive portion of a package, including a die attach pad (DAP); a semiconductor die coupled to the DAP; and a direct bonded metal (DBM) substrate including at least a metal layer coupled to a dielectric layer, the semiconductor die and the DAP being included in a first vertical stack separated from a second vertical stack including the DBM substrate.

In some aspects, the techniques described herein relate to an apparatus, including: a conductive portion of a package, including a die attach pad (DAP); a semiconductor die coupled to the DAP; and a direct bonded metal (DBM) substrate including at least a metal layer coupled to a dielectric layer, the semiconductor die and the DAP being included in a first vertical stack separated from and non-overlapping with a second vertical stack including the DBM substrate; and wherein the first vertical stack of the semiconductor die and the DAP is vertically disposed above or on a DBM recess, wherein the DBM recess is laterally adjacent to the second vertical stack of the DBM substrate.

In some aspects, the techniques described herein relate to a method of making a package, including: forming a direct bonded metal (DBM) substrate including at least a metal layer coupled to a dielectric layer; forming a conductive region of the package including a die attach pad (DAP); and coupling a semiconductor die to an upper surface of the DAP; the semiconductor die and the DAP being included in a first vertical stack separated from a second vertical stack of the DBM substrate.

The details of one or more implementations are set forth in the accompanying drawings and the description below. Other features will be apparent from the description and drawings, and from the claims.

### BRIEF DESCRIPTION OF THE DRAWINGS

FIG. 1 is a cross-sectional view of a semiconductor device package.

FIG. 2 illustrates a top perspective view of an example semiconductor device package including various semiconductor die mounted on a DBM substrate.

FIG. 3 illustrates a cross-sectional view of the semiconductor device package of FIG. 2.

FIG. 4 illustrates an irregular shape DBM substrate.

FIG. 5 is a diagram illustrating a DBM master card that includes a DBM substrate for multiple semiconductor device packages.

FIG. 6A illustrates the master card of FIG. 5 including DBM substrates for multiple semiconductor device packages.

FIG. 6B illustrates two DBM substrates of the master card of FIG. 6A.

FIG. 7 is a flow chart illustrating a method of making a semiconductor device package.

### DETAILED DESCRIPTION

Semiconductor device packages (e.g., semiconductor device modules) should provide high levels of electrical, mechanical, and thermal reliability, in a cost-efficient and space-efficient manner.

Semiconductor device modules can include a direct-bonded metal (DBM) substrate, such as, for example, a direct-bonded copper (DBC) substrate. In some implementations, DBC substrates may be used in some power modules, because of their very good thermal conductivity. In some implementations, a DBC substrate is composed of (or may include) a ceramic oxide substrate (baseplate) (which may be referred to herein as a dielectric layer or ceramic material layer) with a layer of copper coupled to one or both sides by, for example, a high-temperature oxidation process.

As noted, a DBM or DBC substrate may include a dielectric layer (e.g., a ceramic material layer) with direct-bonded metal, for example, a patterned metal layer including one or more patterned metal layer portions disposed on at least one side of the ceramic material layer. A DBM substrate is used in power device modules, and the DBM substrate is usually connected to a metal portion of a power device module (e.g., a leadframe) through soldering. For example, a DBM substrate may be coupled to a die attach pad (DAP) of a leadframe. A DAP may be a portion of the leadframe to which a die is coupled or attached (e.g., soldered) thereto. This connection between DBM substrate and leadframe (e.g., the connection between the DBM substrate and DAP) may involve reflow soldering and/or sintering, which may be a high-temperature process. DBM (e.g., DBC) is prone to deformation at high temperatures and generates stress at the connection with the leadframe. The deformation and stress of DBM at the high temperature can make it prone to cracking, e.g., such as cracking at the dielectric layer of the DBM substrate, leading to device failure.

Although referred to, by way of example, as a leadframe throughout this detailed description, the leadframe can include any type of conductive portion of a package (e.g., conductive portion, conductive terminal) that can provide an external connection point from a package. Accordingly, the leadframe can be referred to as a conductive portion of the package.

Accordingly, described implementations provide a semiconductor device package that includes a conductive portion (e.g., a leadframe) of the package, including a die attach pad (DAP), a semiconductor die coupled to the DAP, and a direct bonded metal (DBM) substrate including at least a metal layer coupled to a dielectric layer. The semiconductor die and the DAP are included in a first vertical stack separated from a second vertical stack including the DBM substrate. For example, the metal layer may be a patterned metal layer or a patterned copper layer. The dielectric layer may be a ceramic or ceramic material layer.

In this manner, an improved semiconductor device package is provided in which there is reduced stress and cracking, e.g., by separating the first vertical stack of the semiconductor die and DAP from the second vertical stack of the DBM substrate. For example, in this manner, by separating (e.g., laterally separating) the DAP from the DBM substrate, the DAP is not soldered to the metal layer of the DBM substrate, thereby avoiding applying a high heat process (or applying less heat) to the DBM substrate, which may reduce stress on the DBM substrate or dielectric layer of the DBM substrate. Also, by separating (e.g., laterally separating) the first vertical stack from the second vertical stack, less rigidity and improved flexibility may be provided in this area of the semiconductor device package, which may relieve strain that may occur below and/or around the DAP, and which may reduce cracking in the dielectric or DBM substrate. Thus, by separating (e.g., laterally separating) the first vertical stack (including semiconductor die and DAP) and the second vertical stack (including the DBM substrate), this may result in fewer device failures or cracks in the dielectric layer of the DBM substrate.

In some implementations, the first vertical stack of the semiconductor die and DAP may be laterally separated from the second vertical stack of the DBM substrate. The first vertical stack of the semiconductor die and DAP may be non-overlapping (e.g., laterally non-overlapping) with the second vertical stack of the DBM substrate. Also, the first vertical stack of the semiconductor die and DAP may be vertically disposed above or on a recess or gap (e.g., a DBM recess or gap), wherein the recess or gap is laterally adjacent to the second vertical stack of the DBM substrate. The first vertical stack of the semiconductor die and the DAP may be laterally separated from and non-overlapping with the second vertical stack of the DBM substrate.

In some implementations, the first vertical stack of the semiconductor die and the DAP may be vertically disposed above or on a DBM recess (which may also be referred to as a DBM gap or DBM cutout area) that is laterally adjacent to the second vertical stack of the DBM substrate.

In some implementations, there may be multiple semiconductor die, with each semiconductor die coupled to a respective DAP. The leadframe may include multiple DAPs, wherein a DAP may be coupled to each semiconductor die. For example, the first vertical stack may include a first semiconductor die coupled to a first DAP, and a third vertical stack may include a second semiconductor die coupled to a second DAP. And, the first vertical stack of the first semiconductor die and first DAP may be separated (e.g., laterally separated) from the second vertical stack of the DBM substrate. And, the third vertical stack of the second semiconductor die and the second DAP may be separated (e.g., laterally separated) from the second vertical stack of the DBM substrate. In these implementations, by separating (e.g., laterally separating) both the first vertical stack (including the first semiconductor die and first DAP) and the third vertical stack (including the second semiconductor die and second DAP) from the second vertical stack (DBM substrate), this may prevent or avoid excess heat from being applied (e.g., from reflow soldering or other high heat process) between the first and second DAPs (of the first vertical stack and a third vertical stack, respectively) and the metal layer of the DBM substrate, e.g., because DAPs are laterally separated from the DBM. In this manner, based on the separation (e.g., lateral separation) of the vertical stacks (e.g., which may include a lateral separation of the DAPs from the DBM substrate), a soldering of the DAP to the metal layer of the DBM is not performed in this area (since these are laterally separated), thereby resulting in fewer device failures or cracks in the dielectric layer of the DBM substrate.

In some implementations, the first DAP and the second DAP may be connected via a connector (or connector portion) of the leadframe. A width of the connector may be less than a width of the first DAP, and a width of the connector may be less than a width of the second DAP.

In some implementations, both the first vertical stack of the first semiconductor die and first DAP, and the third vertical stack of the second semiconductor die and second DAP may be laterally separated from and non-overlapping with the second vertical stack of the DBM substrate.

In some implementations, the first vertical stack of the semiconductor die and the DAP may be vertically disposed above or on a DBM recess (which may also be referred to as a DBM gap or a DBM cutout area) that is laterally adjacent to the second vertical stack of the DBM substrate.

In some implementations, a semiconductor device package may be provided that includes a conductive portion (e.g., leadframe) of the package, including a die attach pad (DAP), a semiconductor die coupled to the DAP, and a direct bonded metal (DBM) substrate including at least a metal layer coupled to a dielectric layer. The semiconductor die and the DAP may be included in a first vertical stack laterally separated from and non-overlapping with a second vertical stack of the DBM substrate.

An integrated circuit (IC) package (e.g., a semiconductor device package) may include at least one semiconductor die mounted on a leadframe structure that includes leads providing external electrical connections (external to the package) for individual devices or integrated circuits in the semiconductor die. The semiconductor die can be mounted on a paddle or die attach pad (DAP) in the leadframe structure using a solder or a conductive adhesive. Wire bonds and/or clips may be used to electrically connect various circuits or devices, or electrically connect an IC or circuit to a leadframe lead, or provide other electrical connection. A wire bond may form a loop (e.g., a vertical loop) that extends from a contact pad on the first semiconductor die to a contact pad on the second semiconductor die or to a post in a leadframe. Further, device contact pads on the semiconductor die may be electrically connected using, for example, wire bonds (e.g., aluminum or copper wire bonds) to respective ones of the leads. The leadframe leads (which may be referred to as leads), which extend to outside of the package body, form external terminal pins that can be used to mount the package on a printed circuit board (PCB) or terminal strip. In some implementations, the terminal pins can be installed in sockets or soldered to a PCB or terminal strip.

For various applications (such as for power applications), the semiconductor device package may include various devices, ICs and/or circuits, e.g., such as silicon devices, silicon carbide transistors, gallium nitride devices, insulated gate bipolar transistor (IGBT), fast recovery diode (FRD), negative temperature coefficient (NTC) thermistors, integrated circuits (ICs), or other devices or circuits.

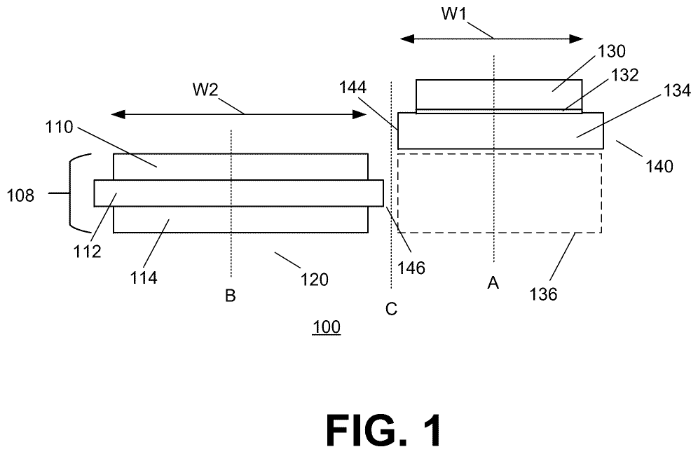

FIG. 1 is a cross-sectional view of a semiconductor device package. As shown in FIG. 1, the semiconductor device package 100 includes a DBM substrate 108 including at least a patterned metal layer 110 (which may include one or more patterned metal layer portions) coupled to a dielectric layer 112 (e.g., which may be ceramic). DBM substrate 108 may also include a lower metal layer 114 that is coupled to a lower side of dielectric layer 112. Patterned metal layer 110 and lower metal layer 114 may be copper or copper alloy, or other metal.

Semiconductor device package 100 may include one or more semiconductor dies, including semiconductor die 130. Semiconductor die 130 may be coupled to an upper surface of die attach pad (DAP) 134 via solder layer 132 or via other technique (such as welding or sintering, or using an adhesive).

If the DBM substrate 108 were to extend under semiconductor die 130 and DAP 134 (not shown in FIG. 1), the coupling (e.g., soldering) of DAP 134 to patterned metal layer 110 of DBM substrate 108 (if DBM substrate 108 were provided under DAP 134) may be or may include a high heat process, which may create stress or strain, or even a crack, within dielectric layer 112, e.g., due to a mismatch in coefficients of thermal expansion (CTE) between the patterned metal layer 110 and DAP 134 (which have relatively high CTEs) and dielectric layer 112 (which typically has a much lower CTE as compared to copper or copper alloy). Therefore, according to example embodiments shown in the structure of FIG. 1, the DBM substrate 108 is not extended under semiconductor die 130 and DAP 134.

Table 1 describes example CTEs of various materials, e.g., including solder (29), patterned metal layer 110 and DAP 134 (both of which may be copper) (17), and dielectric layer 112 (e.g., which may be ceramic) (6.8). Therefore, there is a significant CTE mismatch between CTE of dielectric layer 112 (6.8) and the CTEs of solder, DAP 134 and patterned metal layer 110. As a result, the dielectric layer 112 may have a higher crack risk due to its lowest CTE of all of the materials in Table 1.

TABLE 1
CTE for various materials.

| Material | CTE (ppm/degree C.) |
|---|---|
| Solder | 29 |
| Patterned metal layer 110 (copper) | 17 |
| Dielectric layer 112 (e.g., ceramic) | 6.8 |
| DAP 134 or leadframe (copper) | 17 |

Therefore, to avoid applying a high heat process between the DAP 134 and the DBM substrate 108 (e.g., which in some cases may apply heat to DBM substrate 108 resulting in a crack or defect in the dielectric layer 112), and/or to provide improved flexibility of the semiconductor device package 100 in this area, and thus reduce the strain and possibility of a crack in DBM substrate 108, DBM substrate 108 may be formed or provided that includes a DBM recess 136 (which may alternatively be referred to as a DBM gap or DBM cutout). As shown in FIG. 1, the DBM recess 136 is disposed below the first vertical stack 140 and is aligned along line A. According to example implementations, as shown in FIG. 1, a semiconductor device package 100 may include a conductive portion (e.g., leadframe) that includes a die attach pad (DAP) 134. Semiconductor die 130 may be coupled (e.g., via solder layer 132, or other technique such as sintering or welding) to the DAP 134. DBM substrate 108 includes at least a patterned metal layer 110 coupled to (e.g., welded, sintered or soldered to) dielectric layer 112. DBM substrate 108 may also include a lower metal layer 114 coupled to (e.g., welded, sintered or soldered to) a lower side of dielectric layer 112.

In example embodiments, semiconductor die 130 and DAP 134 are included in a first vertical stack 140 that is separated (e.g., laterally separated) from a second vertical stack 120 (aligned along line B) that includes the DBM substrate 108. First vertical stack 140 may have a width of W1, and second vertical stack 120 may a width of W2, as shown in FIG. 1. By the first vertical stack 140 being laterally separated from second vertical stack 120, this may include width W1 of first vertical stack 140 being laterally separated (e.g., there may be a lateral gap at or around line C between first vertical stack 140 and second vertical stack 120, and/or there may be no lateral overlap between second vertical stack 120 and first vertical stack 140) and/or non-overlapping (does not overlap) with width W2 of second vertical stack 120. In some cases, a lateral or horizontal gap may be provided (or may exist) at line C between an edge 144 of first vertical stack 140 and an edge 146 of second vertical stack 120. In this arrangement where the first vertical stack 140 and second vertical stack 120 are separated and/or non-overlapping, there may be no coupling of DAP 134 of first vertical stack 140 and the patterned metal layer 110 of second vertical stack 120 near dielectric layer 112, such as via a high heat process (e.g., soldering). Therefore, the use of a first vertical stack 140 that is (e.g., laterally) separated and/or non-overlapping with second vertical stack 120, may improve flexibility of a portion of the semiconductor device package 100, may avoid performing a connection or coupling (e.g., soldering, sintering or welding) in this area between DAP 134 and patterned metal layer 110, and may reduce the strain on DBM substrate 108 and/or dielectric layer 112, thereby decreasing the risk of a crack in dielectric layer 112. Therefore, the structure shown in FIG. 1, including a first vertical stack 140 that is separated (e.g., laterally separated) from and/or non-overlapping with second vertical stack 120 may provide improved reliability.

Thus, for example, first vertical stack 140 of the semiconductor die 130 and DAP 134 may be non-overlapping (e.g., laterally non-overlapping) with second vertical stack 120 of DBM substrate 108 (e.g., width W1 of first vertical stack 140 does not laterally overlap with width W2 of second vertical stack 120, shown in FIG. 1). Also, in some example embodiments, first vertical stack 140 including the semiconductor die 130 and the DAP 134 may be vertically disposed above or on DBM recess 136, wherein the DBM recess 136 is laterally adjacent to second vertical stack 120 of the DBM substrate 108 (e.g., DBM recess 136 is laterally to the right of second vertical stack 120, in the example shown in FIG. 1). Thus, it can be seen in example of FIG. 1 that the DBM recess 136, which may include an area where the DBM substrate 108 is not provided or present, is directly below the first vertical stack 140, and is laterally adjacent (e.g., to the right) of the second vertical stack 120. The laterally separated and non-overlapping structure of the first vertical stack 140 of the semiconductor die 130 and DAP 134 with the second vertical stack 120 of the DBM substrate 108 may result in part from DBM recess 136 being provided that is disposed below the first vertical stack 140 (e.g., DBM recess may be directly below first vertical stack 140, and DBM recess may have a same width W1 as first vertical stack 140), and the DBM recess 136 being laterally adjacent to second vertical stack 120.

The separated (e.g., laterally separated) and/or non-overlapping arrangement of the first vertical stack 140 and the second vertical stack 120 may reduce strain applied to part of the semiconductor device package 100 near the DBM substrate 108 that may typically occur, e.g., such as via a high heat coupling or connection process (e.g., soldering) of DAP 134 to patterned metal layer 110. Thus, this arrangement shown in FIG. 1 including laterally separated and/or non-overlapping first vertical stack 140 and second vertical stack 120 may improve package flexibility and/or reduce the likelihood of cracks occurring in the dielectric layer 112 of DBM substrate 108, e.g., since the DBM recess 136 may increase flexibility and decrease rigidity of the semiconductor device package 100 in this area, and/or a soldering or other high heat coupling process is not necessary (and may not necessarily be performed) between DAP 134 and substrate 108 near edge 146 of DBM substrate to couple the DAP 134 to DBM substrate 108. For example, based on the lateral separation between the first vertical stack 140 and second vertical stack 120, and/or the DBM recess 136, soldering or other high heat coupling or connection process is unnecessary and/or not performed to couple the DAP 134 of first vertical stack 140 with patterned metal layer 110 of second vertical stack 120, thereby avoiding high heat being applied to the DBM substrate 108 of second vertical stack 120, and decreasing the likelihood of a crack occurring in dielectric layer 112. As noted, there is a significant CTE mismatch between dielectric layer 112 (which may be ceramic material) and the copper of DAP 134 and patterned metal layer 110, which may cause a crack or fault to occur in the dielectric layer 112 if a high heat process (e.g., soldering) is used to connect DAP 134 to patterned metal layer 110 in this area, e.g., if patterned metal layer 110 is provided below first vertical stack 140 of semiconductor die 130 and DAP 134. However, as noted, a DBM recess 136 may be provided to relieve the strain in this area below and near the first vertical stack 140 by allowing more flexibility and less rigidity since the DAP 134 of first vertical stack 140 is not (or is not necessarily) coupled (e.g., soldered) to patterned metal layer 110 of second vertical stack 120, and thereby eliminate the need for high heat connection process (e.g., soldering) of DAP 134 to patterned metal layer 110, which may reduce the likelihood of a crack forming in DBM substrate 108 based in part on a CTE mismatch between the dielectric layer 112 and copper or copper alloy of DAP 134 and patterned metal layer 110.

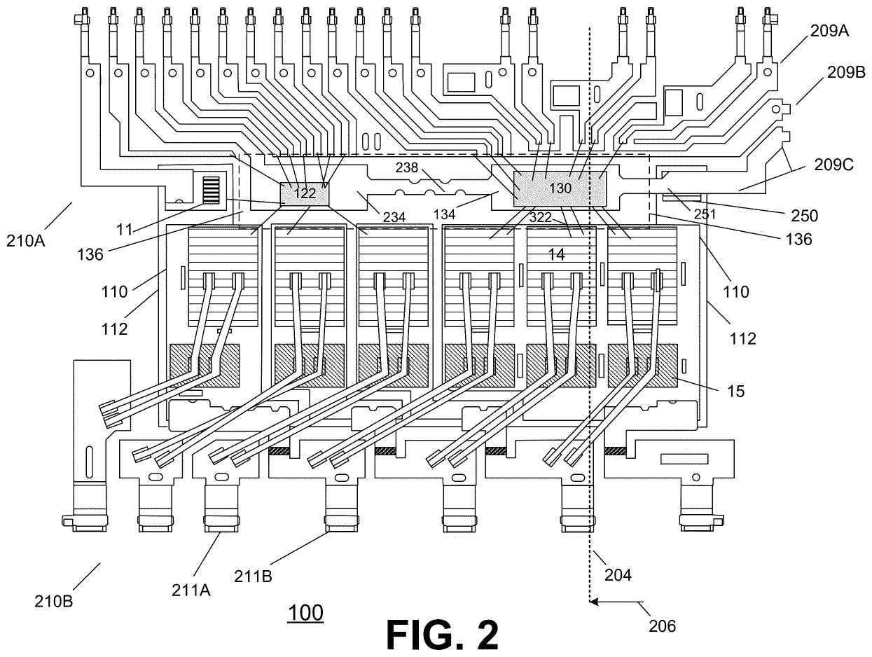

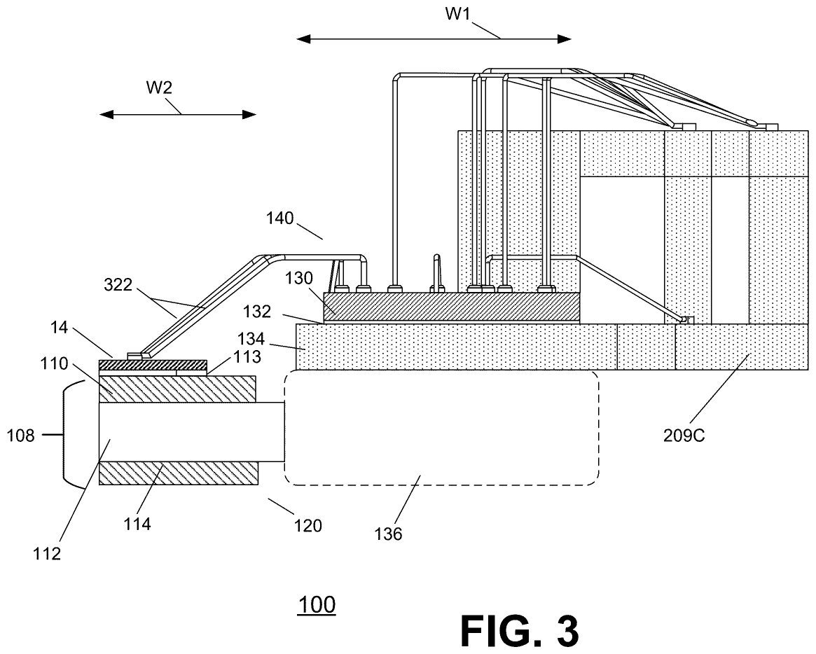

FIG. 2 illustrates a top perspective view of an example semiconductor device package 100 including various semiconductor die mounted on a DBM substrate. FIG. 2 illustrates an example of a semiconductor device package that includes the vertical stack structure (including a first vertical stack and a second vertical stack) shown in FIG. 1. FIG. 3 illustrates a cross-sectional view of the semiconductor device package 100 of FIG. 2. The cross-sectional view of the semiconductor device package 100 shown in FIG. 3 is taken along line 204 from direction 206 of the semiconductor device package 100 of FIG. 2. FIG. 3 illustrates a semiconductor device package that includes a vertical stack structure (including a first vertical stack and a second vertical stack) that is an example implementation of the vertical stack structure of FIG. 1. Within FIGS. 1-3 (and the other FIGs. described herein), the same reference numerals refer to the same elements or items.

Referring to the semiconductor device package 100 shown in FIGS. 2-3, a direct-bonded metal (DBM) substrate 108 (FIG. 3) is provided, and may include a patterned metal layer 110 coupled to a (e.g., soldered, sintered or welded) dielectric layer 112 (e.g., which may be ceramic). DBM substrate 108 may also include a lower metal layer 114 (FIG. 3) coupled (e.g., soldered, sintered or welded) to a lower surface of dielectric layer 112. The patterned metal layer 110 and dielectric layer 112 are also shown in FIG. 2. Semiconductor device package 100 may include one or more semiconductor die, such as semiconductor die 122, semiconductor die 130, semiconductor die 11, semiconductor die 14, and semiconductor die 15. Semiconductor die 14 may be coupled, e.g., soldered (via solder layer 113) (or sintered or welded) to patterned metal layer 110.

For example, semiconductor die 122 may a first controller integrated circuit (IC) chip, semiconductor die 130 may be a second controller IC chip, semiconductor die 11 may be a thermistor, semiconductor die 14 may be a first power device die such as an IGBT, and semiconductor die 15 may be a second power device die such as a FRD die. One or more of these semiconductor die, such as semiconductor die 11, semiconductor die 14 and/or semiconductor die 15, may be mounted on DBM substrate 108, e.g., mounted onto an upper surface of patterned metal layer 110 of DBM substrate 108. For example, semiconductor die 14 may be coupled (e.g., soldered) to patterned metal layer 110 via solder layer 113.

In example embodiments, semiconductor die 130 and DAP 134 (or semiconductor die 130, solder layer 132 and DAP 134) are included in a first vertical stack 140 that is separated (e.g., laterally separated) from and/or non-overlapping with a second vertical stack 120 that includes the DBM substrate 108. Alternatively, the second vertical stack 120 may include semiconductor die 14 and DBM substrate 108 (including patterned metal layer 110, dielectric layer 112 and lower metal layer 114).

In example embodiments, as shown in FIGS. 2-3, DBM substrate 108 may be coupled to leadframe 210A and/or leadframe 210B of semiconductor device package 100. Leadframe 210A may include leadframe lead 209A, leadframe lead 209B, leadframe lead 209C, and other leadframe leads. Leadframe 210B may include leadframe lead 211A, leadframe lead 211B, and other leadframe leads. Leadframe 210A and leadframe 210B may be coupled together or formed together, or may be one leadframe.

Wire bonds and/or clips are provided, which may provide electrical connections between ICs, circuits, devices, leadframe leads, etc. The example wire bonds in FIG. 2 may include wire bonds 322 that electrically connect semiconductor die 130 to semiconductor die 14. Additional wire bonds and/or clips may be provided.

As shown in FIG. 2, leadframe 210A includes die attach pad (DAP) 134 and DAP 234, which are connected or coupled via connector 238. DAP 134, DAP 234 and connector 238 (which connects or couples DAP 134 to DAP 234) may be formed as part of, or connected to, leadframe lead 209C.

Although not shown in FIGS. 1-3, the semiconductor dies, ICs, devices, DBM substrate 108 and other components of semiconductor device package 100 may be encapsulated in a mold body (such as a mold body made of a plastic or an epoxy) to protect the semiconductor dies, ICs, devices and other components of the semiconductor device package 100 against environmental threats such as mechanical impact, chemical contamination, and/or light exposure.

In example embodiments, semiconductor die 130 and DAP 134 are included in a first vertical stack 140 that is separated (e.g., laterally separated) from a second vertical stack 120 that includes the DBM substrate 108. Second vertical stack 120 may include DBM substrate and semiconductor die 14. First vertical stack 140 may have a width of W1, and second vertical stack 120 may a width of W2, as shown in FIG. 3. By the first vertical stack 140 being laterally separated from second vertical stack 120, this may include width W1 of first vertical stack 140 being laterally separated (e.g., there may be a lateral gap and/or no lateral overlap between vertical stacks 120 and 140) and/or non-overlapping (does not overlap) with width W2 of second vertical stack 120. In some cases, a lateral or horizontal gap may be provided first vertical stack 140 and second vertical stack 120. In this arrangement where the first vertical stack 140 and second vertical stack 120 are separated and/or non-overlapping, there may be no coupling of DAP 134 of first vertical stack 140 and the patterned metal layer 110 of second vertical stack 120 near dielectric layer 112, such as via a high heat process (e.g., soldering). Therefore, the use of a first vertical stack 140 that is (e.g., laterally) separated and/or non-overlapping with second vertical stack 120, may improve flexibility (and thus reduce rigidity) of a portion of the semiconductor device package 100, may avoid performing a connection or coupling (e.g., soldering, sintering or welding) in this area between DAP 134 and patterned metal layer 110, and may reduce the strain on DBM substrate 108 and/or dielectric layer 112, thereby decreasing the risk of a crack in dielectric layer 112. Therefore, the structure shown in FIG. 3, including a first vertical stack 140 that is separated (e.g., laterally separated) from and/or non-overlapping with second vertical stack 120 may provide improved reliability.

Thus, for example, first vertical stack 140 of the semiconductor die 130 and DAP 134 may be non-overlapping (e.g., laterally non-overlapping) with second vertical stack 120 of DBM substrate 108. Also, in some example embodiments, first vertical stack 140 including the semiconductor die 130 and the DAP 134 may be vertically disposed above or on DBM recess 136, wherein the DBM recess 136 is laterally adjacent to second vertical stack 120 of the DBM substrate 108 (e.g., DBM recess 136 is laterally to the right of second vertical stack 120, in the example shown in FIG. 1). DBM recess 136, which may include an area where the DBM substrate 108 is not provided or present, is directly below the first vertical stack 140, and is laterally adjacent (e.g., to the right) of the second vertical stack 120. The dashed line of DBM recess 136 in FIGS. 2-3 indicates an area where there is no DBM substrate, or an absence of the DBM substrate. Thus, as shown in FIG. 2, the area (indicated by dashed box of DBM recess 136) surrounding DAP 234, connector 238 and DAP 134 is where the DBM recess 136 is provided, and allows for improved flexibility beneath and/or surrounding the DAP 134 and DAP 234.

Leadframe portion 251 of leadframe lead 209C may be coupled (e.g., soldered, sintered or welded) to a portion 250 of patterned metal layer 110. Portion 250 is a portion of the patterned metal layer 110. However, the improved flexibility, and reduced heat transfer to dielectric layer 112 based on the (e.g., laterally) separated first vertical stack 140 and second vertical stack 120, and thus reduced risk of dielectric cracking, is still provided or present.

The laterally separated and non-overlapping structure of the first vertical stack 140 of the semiconductor die 130 and DAP 134 with the second vertical stack 120 of the DBM substrate 108 may result in part from DBM recess 136 being provided that is disposed below the first vertical stack 140 (e.g., DBM recess 136 may be directly below first vertical stack 140), and the DBM recess 136 being laterally adjacent to second vertical stack 120. The separated (e.g., laterally separated) and/or non-overlapping arrangement of the first vertical stack 140 and the second vertical stack 120 may reduce strain applied to part of the semiconductor device package 100 near the DBM substrate 108 that may typically occur, e.g., such as via a high heat coupling or connection process (e.g., soldering) of DAP 134 to patterned metal layer 110.

Thus, this arrangement shown in FIG. 1 including laterally separated and/or non-overlapping first vertical stack 140 and second vertical stack 120 may improve package flexibility and/or reduce the likelihood of cracks occurring in the dielectric layer 112 of DBM substrate 108, e.g., since the DBM recess 136 may increase flexibility and decrease rigidity of the semiconductor device package 100 in this area. Also, there may be reduced heat transfer to dielectric layer 112 because a soldering or other high heat coupling process is not necessary (and may not be performed) between DAP 134 and substrate 108 near edge 146 of DBM substrate to couple the DAP 134 to DBM substrate 108. For example, based on the lateral separation between the first vertical stack 140 and second vertical stack 120, and/or the DBM recess 136, soldering or other high heat coupling or connection process is unnecessary and/or not performed to couple the DAP 134 of first vertical stack 140 with patterned metal layer 110 of second vertical stack 120, thereby avoiding high heat being applied to the DBM substrate 108 of second vertical stack 120, and decreasing the likelihood of a crack occurring in dielectric layer 112. As noted, there is a significant CTE mismatch between dielectric layer 112 (which may be ceramic) and the copper of DAP 134 and patterned metal layer 110, which may cause a crack or fault to occur in the dielectric layer 112 if a high heat process (e.g., soldering) is used to connect DAP 134 to patterned metal layer 110 in this area, e.g., if patterned metal layer 110 is provided below first vertical stack 140 of semiconductor die 130 and DAP 134. However, as noted, a DBM recess 136 may be provided to relieve the strain in this area below and/or near the first vertical stack 140 by allowing more flexibility and less rigidity since the DAP 134 of first vertical stack 140 is not (or is not necessarily) coupled (e.g., soldered) to patterned metal layer 110 of second vertical stack 120, and thereby eliminate the need for high heat connection process (e.g., soldering) of DAP 134 to patterned metal layer 110, which may reduce the likelihood of a crack forming in DBM substrate 108 based in part on a CTE mismatch between the dielectric layer 112 and copper or copper alloy of DAP 134 and patterned metal layer 110.

A same and/or similar vertical stack arrangement may be present or provided for DAP 234 as described and illustrated for DAP 134 in FIG. 3. That is, for example, an additional vertical stack may be provided that includes semiconductor die 122 and DAP 234, where this additional vertical stack is laterally separated from and/or non-overlapping with the second vertical stack 120 including DBM substrate 108. That is, the DBM recess 136, as shown in FIG. 2, may extend around and beneath DAP 234, connector 238 and DAP 134, as shown by the dashed rectangle for DBM recess 136.

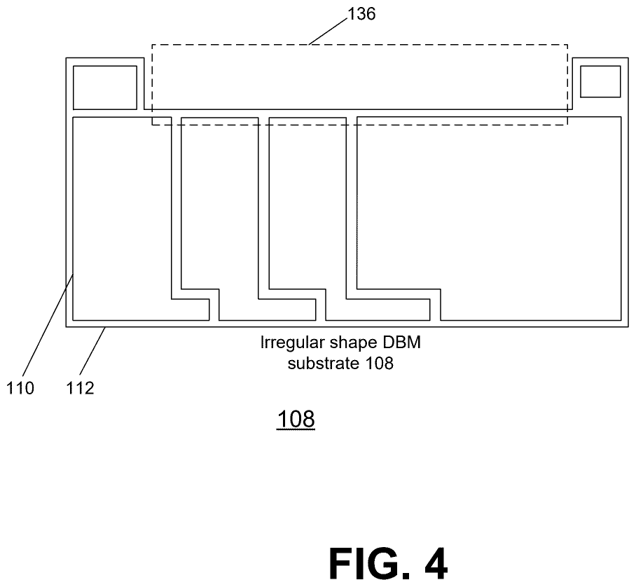

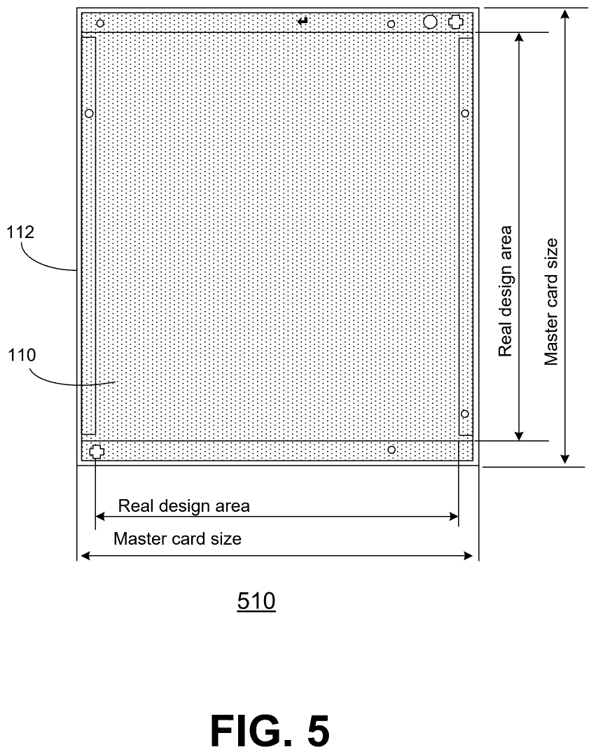

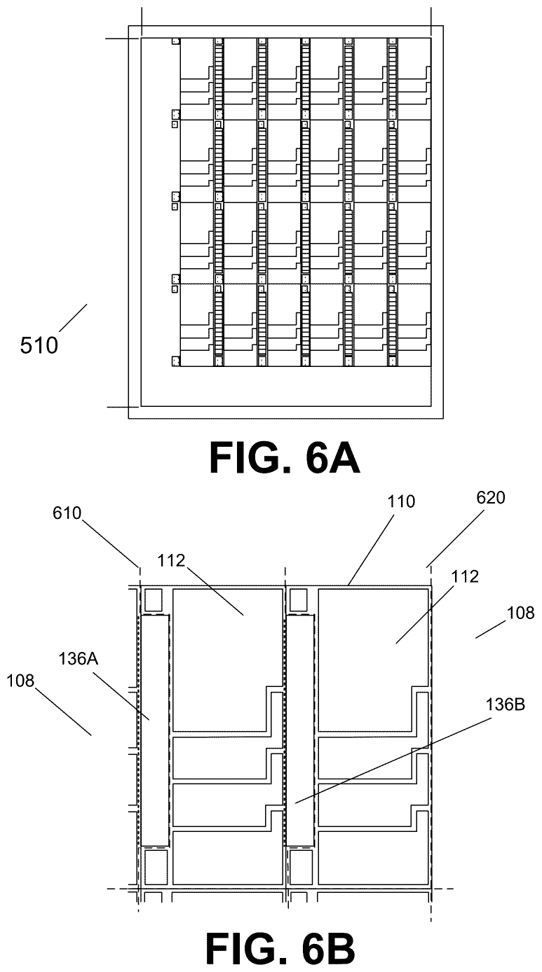

FIG. 4 illustrates an irregular shape DBM substrate. DBM substrate 108 includes at least a patterned metal layer 110 coupled to dielectric layer 112. DBM substrate may be considered to have an irregular shape based on the presence of the DBM recess 136. FIG. 5 is a diagram illustrating a DBM master card that includes a DBM substrate 108 for multiple semiconductor device packages. DBM master card 510 may include a patterned metal layer 110 and a dielectric layer 112, which may be formed for multiple (e.g., 24) semiconductor device packages 100. FIG. 6A illustrates the master card 510 of FIG. 5 including DBM substrates for 24 semiconductor device packages 100. FIG. 6B illustrates two DBM substrates of the master card of FIG. 6A. As shown in FIG. 6B, the DBM substrate 108 for each semiconductor device package 100 may include a patterned metal layer 110 and a dielectric layer 112. Also, a first DBM recess 136A is provided for one DBM substrate 108, and a second DBM recess 136B is provided for another DBM substrate 108. In example embodiments, the separate DBM substrates 108A and 108B may be formed to include a DBM recess 136 for each semiconductor device package 100, including first DBM recess 136A and second DBM recess 136B, e.g., by cutting or separating the DBM substrates 108 by cutting along cutting L-shaped cutting lines 610 and 620. In this manner, even though the DBM substrates 108 on the master card may have an irregular shape, the same number of DBM substrates 108 can be provided in the master card (e.g., 24) as compared to without a DBM recess 136. As a result, there is little to no cost increase to manufacture a master card that employees an irregular shape DMB substrate, as shown in FIG. 4. The DBM recess 136 may be included in the forming of the master card, and/or cutting or separation may be performed along L-shaped cutting lines 610 and 620 to provide for a DBM recess 136 for each semiconductor device package 100, according to example embodiments.

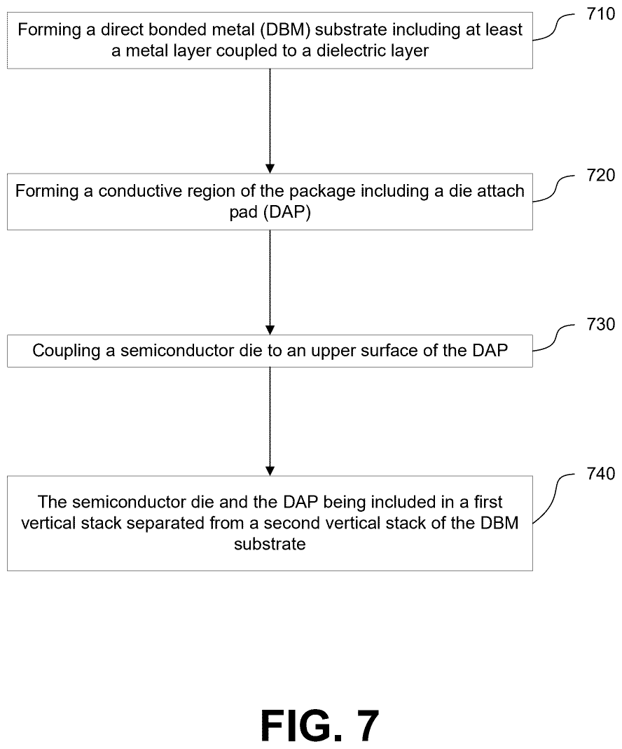

FIG. 7 is a flow chart illustrating a method of making a semiconductor device package 100. Operation 710 includes forming a direct bonded metal (DBM) substrate (e.g., DBM substrate 108, FIGS. 1-3) including at least a metal layer (e.g., patterned metal layer 110, FIGS. 1-3) coupled to a dielectric layer (e.g., dielectric layer 112). Operation 720 includes forming a conductive region (e.g., a leadframe 210A) of the package including a die attach pad (DAP) (e.g., DAP 134, FIGS. 1 and 3). And, operation 730 includes coupling a semiconductor die (e.g., semiconductor die 130, FIGS. 1, 3) to an upper surface of the DAP. At operation 740, the semiconductor die and the DAP being included in a first vertical stack (e.g., semiconductor die 130 and DAP 134 included in a first vertical stack 140, FIGS. 1 and 3) separated from a second vertical stack of the DBM substrate (e.g., second vertical stack 120 of DBM substrate 108, FIGS. 1-3). The method of FIG. 7 may further include forming the DBM substrate to include a DBM recess (e.g., DBM recess 136, FIGS. 1-4), wherein the first vertical stack of the semiconductor die and the DAP is vertically disposed above or on the DBM recess, wherein the DBM recess is laterally adjacent to the second vertical stack of the DBM substrate. Also, with reference to the method of FIG. 7, first vertical stack of the semiconductor die and the DAP is laterally separated from and non-overlapping with the second vertical stack of the DBM substrate.

With references to FIGS. 1-3, for example, semiconductor die 130 and DAP 134 (or semiconductor die 130, solder layer 132 and DAP 134) may be included in a first vertical stack 140 that is separated (e.g., laterally separated) from and/or non-overlapping with a second vertical stack 120 that includes the DBM substrate 108. Alternatively, the second vertical stack 120 may include semiconductor die 14 and DBM substrate 108 (including patterned metal layer 110, dielectric layer 112 and lower metal layer 114). Leadframe 210A may include die attach pad (DAP) 134 and DAP 234, which are connected or coupled via connector 238. DAP 134, DAP 234 and connector 238 (which connects or couples DAP 134 to DAP 234) may be formed as part of, or connected to, leadframe lead 209C.

In example embodiments, semiconductor die 130 and DAP 134 are included in a first vertical stack 140 that is separated (e.g., laterally separated) from a second vertical stack 120 that includes the DBM substrate 108. Second vertical stack 120 may include DBM substrate 108 and semiconductor die 14. First vertical stack 140 may have a width of W1, and second vertical stack 120 may a width of W2, as shown in FIG. 3. By the first vertical stack 140 being laterally separated from second vertical stack 120, this may include width W1 of first vertical stack 140 being laterally separated (e.g., there may be a lateral gap and/or no lateral overlap between vertical stacks 120 and 140) and/or non-overlapping (does not overlap) with width W2 of second vertical stack 120. In some cases, a lateral or horizontal gap may be provided first vertical stack 140 and second vertical stack 120. In this arrangement where the first vertical stack 140 and second vertical stack 120 are separated and/or non-overlapping, there may be no coupling of DAP 134 of first vertical stack 140 and the patterned metal layer 110 of second vertical stack 120 near dielectric layer 112, such as via a high heat process (e.g., soldering). Therefore, the use of a first vertical stack 140 that is (e.g., laterally) separated and/or non-overlapping with second vertical stack 120, may improve flexibility (and thus reduce rigidity) of a portion of the semiconductor device package 100, may avoid performing a connection or coupling (e.g., soldering, sintering or welding) in this area between DAP 134 and patterned metal layer 110, and may reduce the strain on DBM substrate 108 and/or dielectric layer 112, thereby decreasing the risk of a crack in dielectric layer 112. Therefore, the structure shown in FIG. 3, including a first vertical stack 140 that is separated (e.g., laterally separated) from and/or non-overlapping with second vertical stack 120 may provide improved reliability.

The laterally separated and non-overlapping structure of the first vertical stack 140 of the semiconductor die 130 and DAP 134 with the second vertical stack 120 of the DBM substrate 108 may result in part from DBM recess 136 being provided that is disposed below the first vertical stack 140 (e.g., DBM recess 136 may be directly below first vertical stack 140), and the DBM recess 136 being laterally adjacent to second vertical stack 120. The separated (e.g., laterally separated) and/or non-overlapping arrangement of the first vertical stack 140 and the second vertical stack 120 may reduce heat transfer to the dielectric layer 112 in this area, increase flexibility of the semiconductor device package 100 in this area, and thereby reduce strain applied to part of the semiconductor device package 100 near the DBM substrate 108. Thus, this arrangement shown in FIGS. 1-3 including laterally separated and/or non-overlapping first vertical stack 140 and second vertical stack 120 may improve package flexibility and/or reduce the likelihood of cracks occurring in the dielectric layer 112 of DBM substrate 108.

Also, in addition to improved flexibility, this arrangement may result in a reduced heat transfer to dielectric layer 112 because a soldering or other high heat coupling process is not necessary (and may not be performed) between DAP 134 and substrate 108 near edge 146 (FIG. 1) of DBM substrate 108 to couple the DAP 134 to DBM substrate 108. For example, based on the lateral separation between the first vertical stack 140 and second vertical stack 120, and/or the DBM recess 136, soldering or other high heat coupling or connection process is unnecessary and/or not performed to couple the DAP 134 of first vertical stack 140 with patterned metal layer 110 of second vertical stack 120, thereby avoiding high heat being applied to the DBM substrate 108 of second vertical stack 120, and decreasing the likelihood of a crack occurring in dielectric layer 112. As noted, there is a significant CTE mismatch between dielectric layer 112 (which may be ceramic) and the copper of DAP 134 and patterned metal layer 110, which may cause a crack or fault to occur in the dielectric layer 112 if a high heat process (e.g., soldering) is used to connect DAP 134 to patterned metal layer 110 in this area. Therefore, this arrangement may improve reliability of a semiconductor device package 100.

Clause 1. An apparatus, comprising: a conductive portion of a package, including a die attach pad (DAP); a semiconductor die coupled to the DAP; and a direct bonded metal (DBM) substrate including at least a metal layer coupled to a dielectric layer, the semiconductor die and the DAP being included in a first vertical stack separated from a second vertical stack including the DBM substrate.

Clause 2. The apparatus of clause 1, wherein the conductive portion of the package comprises a leadframe.

Clause 3. The apparatus of clause 1, wherein the first vertical stack of the semiconductor die and the DAP is laterally separated from the second vertical stack of the DBM substrate.

Clause 4. The apparatus of clause 1, wherein the first vertical stack of the semiconductor die and the DAP is non-overlapping with the second vertical stack of the DBM substrate.

Clause 5. The apparatus of clause 1, wherein the first vertical stack of the semiconductor die and the DAP is vertically disposed above or on a DBM recess, wherein the DBM recess is laterally adjacent to the second vertical stack of the DBM substrate.

Clause 6. The apparatus of clause 1, wherein the first vertical stack of the semiconductor die and the DAP is laterally separated from and non-overlapping with the second vertical stack of the DBM substrate.

Clause 7. The apparatus of clause 1, wherein the semiconductor die comprises a first semiconductor die, the DAP comprises a first DAP, the apparatus further comprising: a second DAP of the conductive portion, wherein the second DAP is connected to the first DAP via a connector of the conductive portion; a second semiconductor die coupled to the second DAP; wherein a third vertical stack of the second semiconductor die and the second DAP is separated from the second vertical stack of the DBM substrate.

Clause 8. The apparatus of clause 7, wherein the third vertical stack of the second semiconductor die and the second DAP is laterally separated from and non-overlapping with the second vertical stack of the DBM substrate.

Clause 9. The apparatus of clause 7, wherein a width of the connector is less than both a width of the first DAP and a width of the second DAP

Clause 10. The apparatus of clause 7, wherein both the first vertical stack of the first semiconductor die and the first DAP and the third vertical stack of the second semiconductor die and the second DAP are laterally separated from and non-overlapping with the second vertical stack of the DBM substrate.

Clause 11. The apparatus of clause 7, wherein the first vertical stack of the first semiconductor die and the first DAP, the third vertical stack of the second semiconductor die and the second DAP, and the connector are laterally separated from and non-overlapping with the second vertical stack of the DBM substrate.

Clause 12. The apparatus of clause 1, wherein a length and width of the DAP is greater than a length and width, respectively, of the semiconductor die.

Clause 13. The apparatus of clause 7, wherein both the first vertical stack of the first semiconductor die and the first DAP and the third vertical stack of the second semiconductor die and the second DAP are vertically disposed above or on a DBM recess, wherein the DBM recess is laterally adjacent to the second vertical stack of the DBM substrate.

Clause 14. The apparatus of clause 1, wherein the DBM recess comprises a DBM gap or a DBM cutout area that is laterally adjacent to the second vertical stack of the DBM substrate.

Clause 15. The apparatus of clause 1: wherein the metal layer comprises a patterned copper layer coupled to an upper surface of the dielectric layer; wherein the dielectric layer comprises a ceramic layer.

Clause 16. The apparatus of clause 1, wherein the DBM substrate comprises a direct bonded copper (DBC) substrate, comprising: a first copper layer coupled to an upper surface of the dielectric layer; and a second copper layer coupled to a lower surface of the dielectric layer.

Clause 17. The apparatus of clause 1, wherein the semiconductor die is soldered to the DAP.

Clause 18. The apparatus of clause 1, wherein the semiconductor die is welded to the conductive portion.

Clause 19. The apparatus of clause 1, wherein the semiconductor die is sintered to the conductive portion.

Clause 20. An apparatus, comprising: a conductive portion of a package, including a die attach pad (DAP); a semiconductor die coupled to the DAP; and a direct bonded metal (DBM) substrate including at least a metal layer coupled to a dielectric layer, the semiconductor die and the DAP being included in a first vertical stack separated from and non-overlapping with a second vertical stack including the DBM substrate; and wherein the first vertical stack of the semiconductor die and the DAP is vertically disposed above or on a DBM recess, wherein the DBM recess is laterally adjacent to the second vertical stack of the DBM substrate.

Clause 21. The apparatus of clause 25, wherein the conductive portion of the package comprises a leadframe.

Clause 22. A method of making a package, comprising: forming a direct bonded metal (DBM) substrate including at least a metal layer coupled to a dielectric layer; forming a conductive region of the package including a die attach pad (DAP); and coupling a semiconductor die to an upper surface of the DAP; the semiconductor die and the DAP being included in a first vertical stack separated from a second vertical stack of the DBM substrate.

Clause 23. The method of clause 22, further comprising: forming the DBM substrate to include a DBM recess, wherein the first vertical stack of the semiconductor die and the DAP is vertically disposed above or on the DBM recess, wherein the DBM recess is laterally adjacent to the second vertical stack of the DBM substrate.

Clause 24. The method of clause 22, wherein the first vertical stack of the semiconductor die and the DAP is laterally separated from and non-overlapping with the second vertical stack of the DBM substrate.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes. In some implementations, sintering can be, or can include a process of fusing particles together into one solid mass by using, for example, a combination of pressure and/or heat without melting the materials.

In some implementations, the DBM substrate can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, the first metal layer and/or the second metal layer can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate. In some implementations, such as in DBC substrate implementations, the first metal layer and/or the second metal layer is a copper layer.

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor dies may be also connected to lead frame posts by electrical connections such as wirebonds or clips.

In example implementations, a package (e.g., a power module) can be a hybrid device package that includes a semiconductor die or a plurality of semiconductor dies that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

In some implementations, a mold material (e.g., molding material or compound, an encapsulation material) can be or can include a non-conducting layer/material.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer)

In some implementations, a module (e.g., a package including a semiconductor device) can be included in another module. The module can be referred to as a package. For example, one or more modules can be one or more sub modules included within another module. In other words, a first module can be included as a sub module within a second module.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. An apparatus, comprising:
a conductive portion of a package, including a die attach pad (DAP);
a semiconductor die coupled to the DAP; and
a direct bonded metal (DBM) substrate including at least a metal layer coupled to a dielectric layer,
the semiconductor die and the DAP being included in a first vertical stack separated from a second vertical stack including the DBM substrate.

2. The apparatus of claim 1, wherein the conductive portion of the package comprises a leadframe.

3. The apparatus of claim 1, wherein the first vertical stack of the semiconductor die and the DAP is laterally separated from the second vertical stack of the DBM substrate.

4. The apparatus of claim 1, wherein the first vertical stack of the semiconductor die and the DAP is non-overlapping with the second vertical stack of the DBM substrate.

5. The apparatus of claim 1, wherein the first vertical stack of the semiconductor die and the DAP is vertically disposed above or on a DBM recess, wherein the DBM recess is laterally adjacent to the second vertical stack of the DBM substrate.

6. The apparatus of claim 1, wherein the first vertical stack of the semiconductor die and the DAP is laterally separated from and non-overlapping with the second vertical stack of the DBM substrate.

7. The apparatus of claim 1, wherein the semiconductor die comprises a first semiconductor die, the DAP comprises a first DAP, the apparatus further comprising:
a second DAP of the conductive portion, wherein the second DAP is connected to the first DAP via a connector of the conductive portion; and
a second semiconductor die coupled to the second DAP;
wherein a third vertical stack of the second semiconductor die and the second DAP is separated from the second vertical stack of the DBM substrate.

8. The apparatus of claim 7, wherein the third vertical stack of the second semiconductor die and the second DAP is laterally separated from and non-overlapping with the second vertical stack of the DBM substrate.

9. The apparatus of claim 7, wherein a width of the connector is less than both a width of the first DAP and a width of the second DAP.

10. The apparatus of claim 7, wherein both the first vertical stack of the first semiconductor die and the first DAP and the third vertical stack of the second semiconductor die and the second DAP are laterally separated from and non-overlapping with the second vertical stack of the DBM substrate.

11. The apparatus of claim 7, wherein the first vertical stack of the first semiconductor die and the first DAP, the third vertical stack of the second semiconductor die and the second DAP, and the connector are laterally separated from and non-overlapping with the second vertical stack of the DBM substrate.

12. The apparatus of claim 1, wherein a length and width of the DAP is greater than a length and width, respectively, of the semiconductor die.

13. The apparatus of claim 7, wherein both the first vertical stack of the first semiconductor die and the first DAP and the third vertical stack of the second semiconductor die and the second DAP are vertically disposed above or on a DBM recess, wherein the DBM recess is laterally adjacent to the second vertical stack of the DBM substrate.

14. The apparatus of claim 5, wherein the DBM recess comprises a DBM gap or a DBM cutout area that is laterally adjacent to the second vertical stack of the DBM substrate.

15. The apparatus of claim 1,
wherein the metal layer comprises a patterned copper layer coupled to an upper surface of the dielectric layer;
wherein the dielectric layer comprises a ceramic layer.

16. The apparatus of claim 1, wherein the DBM substrate comprises a direct bonded copper (DBC) substrate, comprising:
a first copper layer coupled to an upper surface of the dielectric layer; and
a second copper layer coupled to a lower surface of the dielectric layer.

17. The apparatus of claim 1, wherein the semiconductor die is soldered to the DAP.

18. The apparatus of claim 1, wherein the semiconductor die is welded to the conductive portion.

19. The apparatus of claim 1, wherein the semiconductor die is sintered to the conductive portion.

20. An apparatus, comprising:
a conductive portion of a package, including a die attach pad (DAP);
a semiconductor die coupled to the DAP; and
a direct bonded metal (DBM) substrate including at least a metal layer coupled to a dielectric layer,
the semiconductor die and the DAP being included in a first vertical stack separated from and non-overlapping with a second vertical stack including the DBM substrate; and
wherein the first vertical stack of the semiconductor die and the DAP is vertically disposed above or on a DBM recess, wherein the DBM recess is laterally adjacent to the second vertical stack of the DBM substrate.

21. The apparatus of claim 20, wherein the conductive portion of the package comprises a leadframe.

22. A method of making a package, comprising:
forming a direct bonded metal (DBM) substrate including at least a metal layer coupled to a dielectric layer;
forming a conductive region of the package including a die attach pad (DAP); and
coupling a semiconductor die to an upper surface of the DAP;
the semiconductor die and the DAP being included in a first vertical stack separated from a second vertical stack of the DBM substrate.

23. The method of claim 22, further comprising:
forming the DBM substrate to include a DBM recess, wherein the first vertical stack of the semiconductor die and the DAP is vertically disposed above or on the DBM recess, wherein the DBM recess is laterally adjacent to the second vertical stack of the DBM substrate.

24. The method of claim 22, wherein the first vertical stack of the semiconductor die and the DAP is laterally separated from and non-overlapping with the second vertical stack of the DBM substrate.
